(19) United States
(12) Patent Application Publication
(10) Pub. No.: US 2025/0194059 A1
(43) Pub. Date: Jun. 12, 2025

(54) ELECTRONIC DEVICE COOLING SYSTEM

(71) Applicant: Toyota Motor Engineering & Manufacturing North America, Inc., Plano, TX (US)

(72) Inventors: Timothy Wang, Ann Arbor, MI (US); Roger Akira Kyle, Aubrey, TX (US); Bryan Else Yamasaki, Aubrey, TX (US); Justin K. Shen, Canton, MI (US); Jackson Zhu, Ann Arbor, MI (US); Xiao Xu, Novi, MI (US)

(73) Assignees: Toyota Motor Engineering & Manufacturing North America, Inc., Plano, TX (US); Toyota Jidosha Kabushiki Kaisha, Toyota-shi (JP)

(21) Appl. No.: 18/535,569

(22) Filed: Dec. 11, 2023

(51) Int. Cl. H05K 7/20

(52) U.S. Cl. CPC H05K 7/20945; H05K 7/20909

(57) ABSTRACT

An electronic device cooling system of a vehicle includes a receptacle fluidly coupled to a dedicated climate zone, the receptacle having at least one sensor. The electronic device cooling system also includes an electronic control unit communicatively coupled to an electronic device and the at least one sensor. Upon receiving a signal from the at least one sensor that a temperature of the electronic device exceeds a first threshold temperature, the electronic control unit transmits a notification to the electronic device relating to the temperature and directs cooling air, via the dedicated control zone, to the receptacle.

### TECHNICAL FIELD

The present disclosure generally relates to cooling devices and, more specifically, to electronic device cooling systems integrated within a vehicle.

### BACKGROUND

Cooling systems integrated into electronics that are activated when the electronics of a device begin to overheat beneficially prevent damage to the electronics. Cooling fans may be integrated into computers or other electronic devices. However, cooling fans are less common in personal electronic devices, such as phones or tablets. As such, personal electronic devices may overheat during use, especially when charging and/or when the personal electronic device is communicatively coupled to the electronic systems within a car. Existing cooling systems for electronic devices are not able to continuously monitor the temperature of the electronic device and notify a user to place the electronic device in a cooling area when the electronic device is overheating.

### SUMMARY

In one aspect, an electronic device cooling system of a vehicle includes a receptacle fluidly coupled to a dedicated climate zone, the receptacle including at least one sensor. The electronic device cooling system also includes an electronic control unit communicatively coupled to an electronic device and the at least one sensor. Upon receiving a signal from the at least one sensor that a temperature of the electronic device exceeds a threshold temperature, the electronic control unit transmits a notification to the electronic device relating to the temperature and directs cooling air, via the dedicated climate zone, to the receptacle.

These and additional objects and advantages provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts an interior of a vehicle with an electronic device cooling system according to one or more embodiments shown and described herein;

FIG. 2 depicts a receptacle of the electronic device cooling system according to one or more embodiments shown and described herein; and

FIG. 3 depicts a cutaway side view of an illustrative electronic device cooling system according to one or more embodiments shown and described herein.

### DETAILED DESCRIPTION

The systems and methods described herein generally relate to electronic device cooling systems that include various features that assist in cooling electronic devices while in a vehicle. The features of the systems and methods described herein that assist in cooling generally function by determining a temperature of the electronic device, transmitting a notification to the electronic device relating to temperature, and directing cooling air to a receptacle in which the electronic device is placed. The various features may be integrated into the vehicle, such as the notification being transmitted through one or more speakers of a vehicle and/or a vehicle head unit.

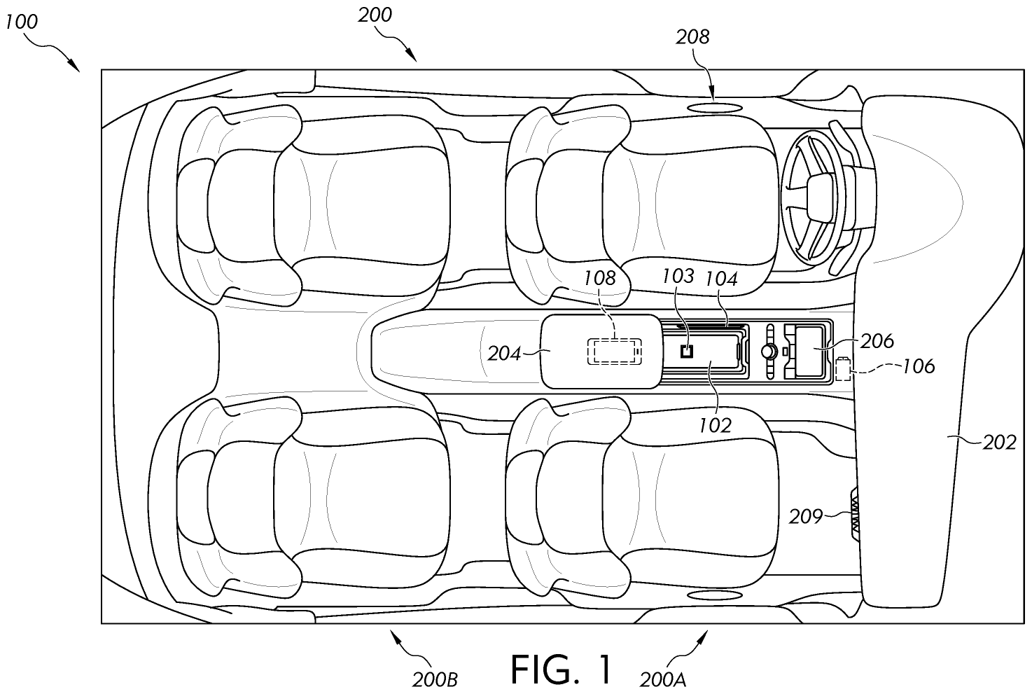

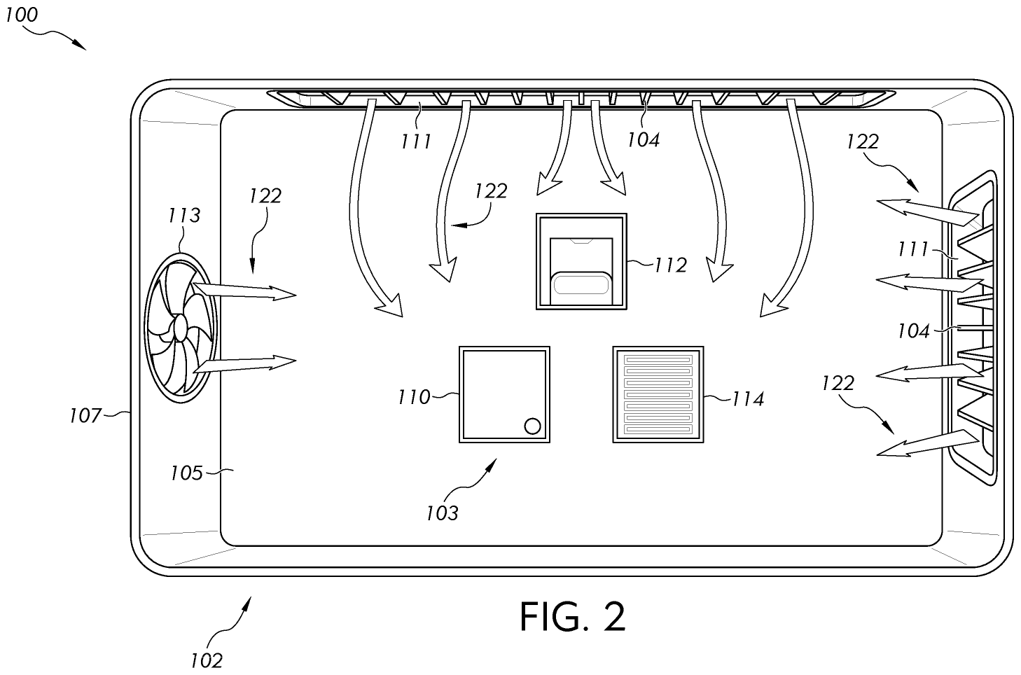

Referring now to FIG. 1, an electronic device cooling system 100 of a vehicle 200 is illustrated. The electronic device cooling system 100 includes a receptacle 102 fluidly coupled to a dedicated climate zone 104. That is, the receptacle 102 is located within the dedicated climate zone 104 such that a vent or the like that delivers cooling fluid received via conduit from a vehicle HVAC system is delivered to the receptacle 102 via a receptacle vent 111 (depicted in FIG. 2). The receptacle 102 may include at least one sensor 103 disposed therein. An electronic control unit 106 may be communicatively coupled to an electronic device 108 and the at least one sensor 103.

The receptacle 102 may be shaped and/or sized to house the electronic device 108 therein. The receptacle 102 may be large enough to house various types and brands of electronic devices 108. In embodiments, the receptacle 102 may be large enough to house computers, tablets, phones, or other like electronic devices 108 that a user may be carrying in the vehicle 200. The receptacle 102 may be a standalone structure, such that the receptacle is attached or mounted to an existing structure within a vehicle interior. In other embodiments, the receptacle 102 may be integrated into existing structures within the vehicle interior. For example, the receptacle 102 may be integrated into a vehicle dashboard 202, a vehicle console 204, or any other part of the vehicle interior. The receptacle 102 may be open or may be enclosed or enclosable.

The receptacle 102 may be located within a front passenger compartment 200A of the vehicle 200 such that front passengers may utilize the electronic device cooling system, within a rear passenger compartment 200B of the vehicle 200 such that rear passengers may utilize the electronic device cooling system 100, or within both the front passenger compartment 200A and the rear passenger compartment 200B. The vehicle 200 may include one, two, three, four, five, or more than five electronic device cooling systems 100. In some embodiments, the number of receptacles 102 of the electronic device cooling system 100 may correspond to a number of seats within the vehicle 200. The vehicle 200 may be any car, truck, van bus, boat, aircraft, or any other vehicle capable of transporting passengers.

The vehicle 200 may also include a vehicle head unit 206, which may be a graphical user interface that is integrated into the vehicle dashboard 202. The vehicle head unit 206 may be communicatively coupled to the electronic control unit 106. The electronic control unit 106 may be communicatively coupled to the electronic device 108 and the at least one sensor 103. As such, the electronic device cooling system 100 may include a communication path that communicatively couples various components of the electronic device cooling system 100 and the vehicle 200. As used herein, the phrase “communicatively connected” or “communicatively coupled” means that coupled components are capable of exchanging data signals with one another such as, e.g., electrical signals via a conductive medium, electromagnetic signals via air, optical signals via optical waveguides, and the like.

Accordingly, the communication path may be formed from any medium that is capable of transmitting a signal such as, e.g., conductive wires, conductive traces, optical waveguides, and the like. In some embodiments, the communication path may facilitate the transmission of wireless signals, such as Wi-Fi, Bluetooth®, Near-Field Communication (NFC), and the like. Moreover, the communication path may be formed from a combination of mediums capable of transmitting signals. In one embodiment, the communication path comprises a combination of conductive traces, conductive wires, connectors, and buses that cooperate to permit the transmission of electrical data signals to components such as processors, memories, sensors, input devices, output devices, and communication devices. Accordingly, the communication path may comprise a vehicle bus, such as for example a LIN bus, a CAN bus, a VAN bus, and the like. Additionally, it is noted that the term “signal” means a waveform (e.g., electrical, optical, magnetic, mechanical, or electromagnetic), such as DC, AC, sinusoidal-wave, triangular-wave, square-wave, vibration, and the like, capable of traveling through a medium.

Referring now to FIG. 2, the at least one sensor 103 of the electronic device cooling system 100 is illustrated. The at least one sensor 103 may include various types of sensors. In some embodiments, the at least one sensor may include a temperature sensor 110. The temperature sensor 110 may be integrated into a bottom surface 105 of the receptacle 102, such that the temperature sensor 110 monitors the temperature of the electronic device 108 when the electronic device 108 is placed within the receptacle 102.

In other embodiments, the temperature sensor 110 may be a temperature sensor of the electronic device 108, such that the temperature sensor 110 is integrated into the electronic device 108. Thus, when the temperature sensor 110 is integrated into the electronic device 108, the electronic device 108 does not have to be placed within the receptacle 102 in order for the electronic device cooling system 100 to monitor the temperature of the electronic device 108; rather, the electronic device 108 may be communicatively coupled to the electronic device cooling system 100 and send temperature information of the electronic device 108 to the electronic device cooling system 100.

The at least one sensor 103 may also include a sensor that provides information to the electronic control unit 106 regarding whether the electronic device 108 is within the receptacle (e.g., a presence sensor or the like). In embodiments, the at least one sensor 103 may include an optical sensor 112 communicatively coupled to the electronic control unit 106. The optical sensor 112 may be used to determine a change in light when the electronic device 108 has been placed within the receptacle 102. The optical sensor 112 may be placed on the bottom surface 105 of the receptacle 102, a side wall 107 of the receptacle 102, or even outside of the receptacle 102, so long as the optical sensor 112 is oriented in such a way as to determine whether the electronic device 108 is within the receptacle 102.

In other embodiments, the at least one sensor may be a force sensor 114 communicatively coupled to the electronic control unit 106. The force sensor 114 may be positioned at a bottom surface 105 of the receptacle and may sense a change of weight when the electronic device 108 when placed within the receptacle. The force sensor 114 may be any sensor capable of sensing a weight of the electronic device 108, such as but not limited to a pressure sensor, a strain gauge, a piezoelectric force sensor, or any other suitable force sensor.

In some embodiments, the at least one sensor 103 may be capable of distinguishing whether the electronic device 108 is placed in the receptacle or whether an object other than the electronic device is placed within the receptacle. For example, the optical sensor 112 may determine the electronic device 108 has been placed within the receptacle 102 based on dimensions of the object placed within the receptacle 102. The electronic device 108 may be generally square/rectangular in shape and have a certain thickness, while other objects such as a set of keys would not have such a shape. In addition, the force sensor 114 may be calibrated to recognize the weight of a specific electronic device 108 and may distinguish this weight from the weight of other objects and, thus, determine whether the electronic device 108 is within the receptacle 102.

As noted hereinabove, the electronic device 108 may be utilizing various applications while connected to the electronic control unit 106 of the vehicle 200. The electronic device 108 may also be charging. As such, the electronic device 108 may tend to overheat, as a battery of the electronic device 108 is being strained. The electronic control unit 106 may receive a signal from the at least one sensor 103 that a temperature of the electronic device 108 exceeds a first threshold temperature. Upon receiving such a signal, the electronic control unit 106 may transmit a notification to the electronic device 108 relating to the temperature and direct cooling air 122 (depicted in FIG. 2) to the receptacle 102 via the dedicated climate zone 104. The first threshold temperature may be a temperature at which it is unsafe or harmful for the electronic device 108 to operate, such as at or above 95° F., at or above 100° F., at or above 105° F., at or above 108° F., at or above 110° F., at or above 112° F., at or above 114° F., at or above 115° F., or greater than 115° F. In some embodiments, the first threshold temperature is slightly lower than the temperature at which it is unsafe or harmful for the electronic device 108 to operate so that the electronic device 108 does not reach the unsafe or harmful temperature before being placed into the receptacle 102 for cooling, as described further below.

Once the electronic control unit 106 receives a signal from the temperature sensor 110 that the temperature of the electronic device 108 exceeds the first threshold temperature, the electronic control unit 106 may transmit a notification to the electronic device 108. The notification may include information about the electronic device 108 temperature, such as a notification that the electronic device 108 is overheating. Moreover, the notification may direct the user to place the electronic device 108 within the receptacle 102 for cooling. The notification may also include other suggestions to reduce the temperature of the electronic device 108, such as temporarily stopping charging or closing out applications.

The user may also be notified regarding the temperature of the electronic device 108 through the vehicle 200. For example, the electronic control unit 106 may transmit the notification to the user through the vehicle head unit 206, as depicted in FIG. 1. In other embodiments, the electronic control unit 106 further transmits the notification via one or more speakers 208. The electronic control unit 106 may transmit the notification through one or all of the electronic device 108, the vehicle head unit 206, and/or the one or more speakers 208.

Once the user places the electronic device 108 into the receptacle 102, the electronic control unit 106 may activate a fan of the dedicated climate zone 104 (upon detection that the electronic device 108 has been placed into the receptacle, such as through the optical sensor 112 or the force sensor 114) to direct cooling air 122 into the receptacle 102 and, thus, cool the electronic device 108. The cooling air 122 from the dedicated climate zone 104 may be cooled air directly from a vehicle climate control system, such as conditioned air from the receptacle vent 111, which may be separate from a vehicle vent 209. The dedicated climate zone 104 may also include the receptacle vent 111 within the receptacle. The receptacle vent 111 is depicted as being within the side wall 107 of the receptacle 102, but it should be understood that the receptacle vent 111 may be underneath the bottom surface 105 of the receptacle 102 or on a top surface of the receptacle 102 in cases in which the receptacle 102 is enclosed. There may be one, two (as depicted in FIG. 2), three, four, or more than four receptacle vents 111 within the receptacle 102.

The dedicated climate zone 104 may be controlled independently of the rest of the vehicle cabin. For example, heat may be forced through vehicle vents 209 pointed toward the passengers, while cooling air 122 may be forced through the receptacle vent 111 pointed toward the electronic device 108. Thus, passengers may maintain the vehicle cabin at a warmer temperature than the temperature of the receptacle 102 through independent control of the dedicated climate zone 104 to the receptacle 102.

In embodiments, cooling air 122 may also be directed to the electronic device 108 within the receptacle 102 by an external fan 113. The external fan 113 may be mounted adjacent to the receptacle 102 and direct cooling air 122 into the receptacle 102 to cool the electronic device 108. In other embodiments, the external fan 113 is mounted within the receptacle, but not connected to the vehicle climate control system, such that no conditioned air (e.g., ambient air) from the vehicle climate control system is run through the external fan 113.

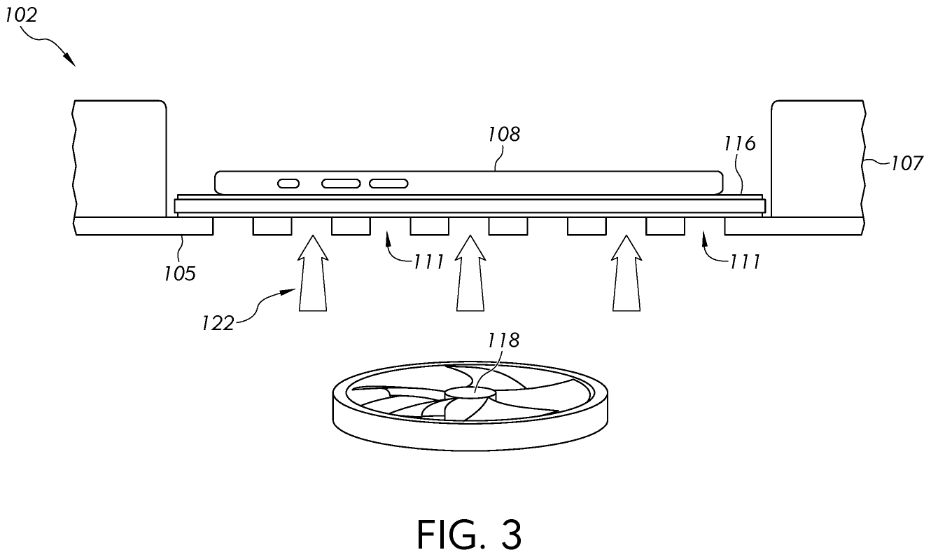

Referring now to FIG. 3, in embodiments, the receptacle 102 may include a wireless charging pad 116 and at least one fan 118 configured to cool the wireless charging pad 116. The wireless charging pad 116 may charge the electronic device 108 when the electronic device 108 is placed on the wireless charging pad 116, as depicted in FIG. 3. The wireless charging pad 116 may take up some or all of the bottom surface 105 of the receptacle 102. In embodiments where the wireless charging pad 116 takes up some or all of the bottom surface 105 of the receptacle, the at least one sensor 103 may be integrated on the wireless charging pad 116 or on the side wall 107 of the receptacle 102.

As noted hereinabove, charging the electronic device 108 may increase the temperature of the electronic device 108. The temperature of the wireless charging pad 116 may also increase when charging the electronic device 108. As such, the least one fan 118 may be configured to cool the wireless charging pad 116. The at least one fan 118 may be on top of, beside, or below the wireless charging pad 116. In embodiments where the at least one fan 118 is below the wireless charging pad 116, the bottom surface 105 of the receptacle 102 may include the receptacle vents 111. The receptacle vents 111 may allow the cooling air 122 to pass through the bottom surface 105 of the receptacle 102 and cool the wireless charging pad 116. The at least one fan 118 may be activated to provide the cooling air 122 when the wireless charging pad 116 exceeds a third threshold temperature (which may be the same or different than the first threshold temperature) and may deactivate when the wireless charging pad 116 is below a fourth threshold temperature (which may be the same or different than the second threshold temperature).

It should now be understood that the embodiments disclosed herein include electronic device cooling systems for use within a vehicle. The electronic device cooling system may notify a user when an electronic device begins to overheat and may direct the user to insert the electronic device into a receptacle of the electronic device cooling system. Cooling air may then be directed to the electronic device to reduce the temperature of the electronic device, making it safe for use.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the present disclosure, including, but not limited to, embodiments defined in the appended claims. More specifically, although some aspects of the present disclosure are identified herein as preferred or particularly advantageous, it is contemplated that the present disclosure is not necessarily limited to these aspects.

What is claimed is:

1. An electronic device cooling system of a vehicle, the electronic device cooling system comprising:
a receptacle fluidly coupled to a dedicated climate zone, the receptacle comprising at least one sensor; and
an electronic control unit communicatively coupled to an electronic device and the at least one sensor, wherein, upon receiving a signal from the at least one sensor that a temperature of the electronic device exceeds a first threshold temperature, the electronic control unit:
transmits a notification to the electronic device relating to the temperature; and
directs cooling air, via the dedicated climate zone, to the receptacle.

2. The electronic device cooling system of claim 1, wherein the notification further provides instructions to a user to insert the electronic device into the receptacle.

3. The electronic device cooling system of claim 1, wherein the electronic control unit further transmits the notification via a vehicle head unit.

4. The electronic device cooling system of claim 1, wherein the electronic control unit further transmits the notification via one or more speakers.

5. The electronic device cooling system of claim 1, wherein the electronic control unit controls at least one fan to decrease air-flow to the receptacle when an electronic device temperature is below a second threshold temperature, wherein the second threshold temperature is less than the first threshold temperature.

6. The electronic device cooling system of claim 1, wherein the receptacle comprises a wireless charging pad and at least one fan configured to cool the wireless charging pad.

7. The electronic device cooling system of claim 1, wherein the at least one sensor comprises a temperature sensor.

8. The electronic device cooling system of claim 1, wherein the at least one sensor comprises an optical sensor.

9. The electronic device cooling system of claim 1, wherein the at least one sensor comprises a force sensor.

10. The electronic device cooling system of claim 1, wherein the receptacle is integrated into a vehicle dashboard.
